(19) United States
(12) Patent Application Publication
(10) Pub. No.: US 2021/0267104 A1
(43) Pub. Date: Aug. 26, 2021

(54) SUBSTRATE MAGAZINE FOR LOADING OR UNLOADING DEVICES

(71) Applicant: Asys Automatisierungssysteme GmbH, Dornstadt (DE)

(72) Inventors: Jürgen Lehner, Laichingen (DE); Klaus Mang, Blaubeuren (DE)

(21) Appl. No.: 17/185,203

(22) Filed: Feb. 25, 2021

(30) Foreign Application Priority Data
Feb. 25, 2020 (DE) 20 2020 101 033.6

(51) Int. Cl. H05K 13/02

(52) U.S. Cl. CPC H05K 13/021

(57) ABSTRACT

A substrate magazine system for loading or unloading devices on production lines has at least one substrate magazine that has two side walls arranged at a distance from, and oriented in parallel to, each other, between which is a plurality of compartments one above the other. The compartments can store one or more flat substrates. Each compartment is formed by two guide rails arranged at a distance from and opposite each other at the side walls. At least one of the side walls is displaceably mounted for changing the clear width between the side walls, and has at least one substrate handling device in, at, or on which the at least one substrate magazine can be arranged. The substrate handling device has a first actuator which can be connected to the displaceably mounted side wall by an actuatable coupling and is designed to displace the displaceable side wall in the connected state.

### PRIORITY AND CROSS REFERENCE TO RELATED APPLICATIONS

This application claims the priority benefit of German Application No. DE 20 2020 101 033.6, filed Feb. 25, 2020, the entirety of which is incorporated by reference herein.

### FIELD

The present application relates to substrate magazines for loading or unloading devices on production lines.

### BACKGROUND

Substrate magazine systems are known. Substrate magazines are used for handling substrates in production lines in order to hold substrates available before processing, for example in the form of substrate blanks, to hold them temporarily during processing, for example for transportation, and to store them after processing for further use or processing.

### SUMMARY

Some embodiments relate to a substrate magazine for loading or unloading devices on production lines, comprising at least one substrate magazine that has two side walls arranged at a distance from each other and oriented in parallel to each other, between which a plurality of compartments lying one above the other is formed, wherein the compartments are each formed for the storage of one or more flat substrates, such as circuit boards, in particular blanks, solar cells or wafers, and wherein each compartment is formed in each case by two guide rails, which at the side walls are arranged at a distance from each other and opposite each other, wherein at least one of the side walls is displaceably mounted for changing the clear width between the side walls, and comprising at least one substrate handling device in, at or on which the at least one substrate magazine for handling substrates can be arranged.

### BRIEF DESCRIPTION OF THE DRAWINGS

FIG. 1 shows an embodiment of a substrate magazine system according to the present disclosure in a simplified side view.

FIG. 2 shows an embodiment of a substrate magazine system according to the present disclosure in a simplified plan view.

### DETAILED DESCRIPTION

Substrate magazines are used for simultaneously accommodating a plurality of substrates so that when a substrate magazine is being transported, all substrates located therein can be transported along with it. In the case of flat substrates, they are regularly inserted into compartments of a substrate magazine, as a result of which a plurality of substrates can be stored in a substrate magazine. In particular, a plurality of substrates can also be inserted into a compartment side by side. In order to ensure that substrate blanks or already populated or processed substrates are not damaged, the substrates are held in the respective compartment by the guide rails only at two side edges facing away from each other, so that the respective substrate rests on a guide rail only at its outer edge. This ensures that electrical/electronic components located on the substrate are not damaged by storage.

Substrate handling devices, such as loading and unloading devices or transportation devices, are used to accommodate one or more substrate magazines and to in an automated manner remove substrates or insert them into the substrate magazine or to transport the substrate magazine as a whole. From the as yet unpublished patent application DE 10 2019 211 603, a substrate magazine is already known which in addition has a displaceable side wall in order to change the distance of the side walls from each other or the clear width between the side walls, whereby the width of the compartments can be changed in order to adapt the substrate magazine for accommodating substrates of different widths.

Some embodiments are based on the object of providing an improved substrate magazine system by means of which an improved handling of substrates, in particular an improved handling of different substrates, for example in different assembly lines, is made possible by one and the same substrate magazine. This makes it possible to improve re-use and further use of a substrate magazine for an operation and to thus reduce the total number of substrate magazines required, for example.

In some embodiments, the object is achieved by a substrate magazine system (1) for loading or unloading devices on production lines, comprising at least one substrate magazine (2) that has two side walls (13, 14) arranged at a distance from each other and oriented in parallel to each other, between which a plurality of compartments (15) lying one above the other is formed, wherein the compartments (15) are each formed for the storage of one or more flat substrates (18), and wherein each compartment (15) is formed in each case by two guide rails (16, 17), which at the side walls (13, 14) are arranged at a distance from each other and opposite each other, wherein at least one of the side walls (14) is displaceably mounted for changing the clear width between the side walls (13, 14), and comprising at least one substrate handling device (3) in, at or on which the at least one substrate magazine (2) for handling substrates (18) can be arranged, characterized in that the substrate handling device (3) has a first actuator (28) which can be connected by an actuatable coupling (34) to the displaceably mounted side wall (14) and is designed in the connected state to displace the displaceable side wall (14). This has the advantage that the at least one substrate magazine can be adapted in an automated manner to substrates that are to be accommodated. The substrate magazine is in this case adapted by an external actuator so that the actuator itself does not have to be moved along with the substrate magazine, which results in advantages firstly with regard to the weight of the substrate magazine and secondly also with regard to the installation space of the substrate magazine. In addition, a purely mechanical design of the substrate magazine is thereby made possible because the actuator and thus the control electronics which may be present for controlling the actuator are likewise located externally. According to some embodiments, it is provided for this purpose that the substrate handling device has a first actuator which can be connected to the displaceably mounted side wall by an actuatable coupling and is designed in the connected state to displace the side wall. The actuator is thus arranged externally on the substrate handling device and can be connected by the coupling to the displaceably mounted side wall in order to displace it. The substrate magazine is thus adapted in an automated manner to in particular different substrate widths not by the substrate magazine itself but by the substrate handling device. This makes possible a simple structural design of the substrate magazine, as already described above.

According to a preferred embodiment, the substrate magazine has a spindle drive which is assigned to the displaceably mounted side wall and can be connected by the coupling to the actuator. A simple and precise displacement of the displaceably mounted side wall is ensured by the spindle drive. The spindle drive has, for example, a drive spindle which extends in the direction of displacement of the side wall, as well as a spindle nut or a spindle thread, which is in engagement with an external thread of the drive spindle and is arranged in a rotationally fixed manner on the side wall. If the drive spindle is now rotated, the rotational movement of the drive spindle is transformed into a translational sliding movement of the side wall. The side wall is in particular displaceably mounted on a frame of the substrate magazine, for example by means of a rail system or guide rod system. The spindle drive is a purely mechanical device which is integrated in the substrate magazine. As a result of the connection to the first actuator by means of the coupling, the spindle drive can be driven and the side wall can thus be displaced. This results in a simple and cost-effective implementation of side-wall displacement.

Particularly preferably, the spindle drive has the aforementioned drive spindle, which has a first coupling element at a free end, wherein the first actuator has a drive shaft which has a second coupling element at a free end, wherein the first and the second coupling element together form the actuatable coupling. The arrangement of the coupling elements on the drive spindle and on the drive shaft ensures a direct connection between the actuator and the spindle drive, which is space-saving and low-wearing.

Preferably, at least one of the coupling elements is displaceable for engaging and disengaging the coupling. By displacing the one coupling element, an operative connection to the other coupling element can thus be established or be released, depending on whether the displaceable coupling element is moved in the direction of or away from the one coupling element. The displaced arrangement of the coupling elements ensures a simple mechanical operative connection of the actuator to the side wall, in particular to the spindle drive.

A second actuator for displacing the said second actuator is particularly preferably arranged in the displaceable coupling element. This ensures that engagement takes place independently of the drive for displacing the side wall and that it is possible at any time to release the connection independently of the drive of the side wall. This in particular meets safety precautions which take effect in the event of a malfunction of the first actuator. If, for example, a malfunction of the first actuator is detected, the second actuator is controlled to disengage the coupling in order to release the operative connection to the substrate magazine.

The substrate handling unit particularly preferably has the first and/or the second actuator. The two actuators are thus preferably assigned to the substrate handling unit and are carried along therewith independently of the substrate magazine. As a result, all of the actuators required for adjusting the clear width of the substrate magazine are located externally and safe operation of the substrate magazine or safe use of the substrate magazine in the substrate magazine system is ensured.

According to a preferred embodiment, the coupling elements form a friction coupling. For this purpose, the coupling elements are designed, for example, as friction disks whose end faces can be pressed against each other by the second actuator so that a torque of the first actuator can be transmitted to the spindle drive by static friction. The design as a friction coupling has the advantage that the coupling elements can be brought together irrespective of their rotational position relative to each other.

Alternatively, the coupling elements are designed to form a dog coupling. For this purpose, the coupling elements are designed such that they form a form-fitting connection with each other in the circumferential direction when they are pushed together by the second actuator. The form-fitting connection ensures that particularly high torques can be transmitted. The only disadvantage in this respect is that the two coupling elements must be aligned with each other in order to enable interlocking.

The second coupling element, that is to say the coupling element permanently connected to the first actuator, is preferably mounted on the drive shaft in a rotationally fixed and axially displaceable manner. This ensures that the second coupling element can always be acted upon by the torque of the first actuator and can establish engagement with the substrate magazine by axial displacement. The second actuator is correspondingly designed to displace the second coupling element axially.

According to a preferred embodiment, the first actuator is designed as an electric motor. This ensures precise adjustment of the substrate magazine by electrical/electronic control by means of a corresponding control unit. In particular, the electric motor allows the side wall to be displaced in both slide directions in a simple manner.

According to a preferred embodiment, the second actuator is designed as a pneumatic or hydraulic actuator or as an electromotive or electromagnetic actuator. This enables simple actuation of the coupling. The embodiment as a pneumatic actuator is particularly advantageous if the substrate handling unit has a pneumatic device anyway which can also be used to operate the second actuator.

The substrate handling unit particularly preferably has a storage table on which at least one substrate magazine can be arranged. Safe handling of the substrate magazine at the substrate handling unit is thereby made possible. In particular, the storage table enables an advantageous alignment of the substrate magazine with respect to the actuator device of the substrate handling unit, which has the first and the second actuator.

According to a preferred embodiment, the storage table has guide means by means of which the at least one substrate magazine on the storage table can be displaced into a final storage position in such a way that the coupling elements are opposite each other in the final storage position of the substrate magazine. The substrate magazine is thus guided in a form-fitting manner by the guide means on the storage table in such a way that, in the final storage position of the substrate magazine, the connection of the actuator device to the displaceable side wall can be established by a control action, in particular of the second actuator. The guide means thus permit an advantageous assignment of the coupling elements to each other, which avoids a subsequent alignment of the actuator unit with respect to the substrate magazine.

The substrate handling unit is particularly preferably designed as a loading and/or unloading device for a production line. For this purpose, the substrate handling unit preferably has at least one device for loading and/or unloading flat substrates which, for example, a conveyor belt, a gripper, a pusher and/or a vacuum suction device.

According to another embodiment, the substrate handling unit is preferably designed as a trolley. For this purpose, the trolley has in particular means of locomotion, such as a drive motor and at least three drive wheels, as well as means for braking and for steering. In particular, the trolley takes the form of an autonomously traveling trolley by means of which substrate magazines can be moved from one location to another in an automated manner. The substrate magazine system particularly preferably comprises a plurality of substrate magazines which are designed like the previously described substrate magazine. Each substrate magazine is thus adjustable with regard to its clear width by the substrate handling unit, so that, independently of the substrate magazine used, different substrates of different substrate widths can be used by the substrate handling unit adapting the clear width of the respective substrate magazine.

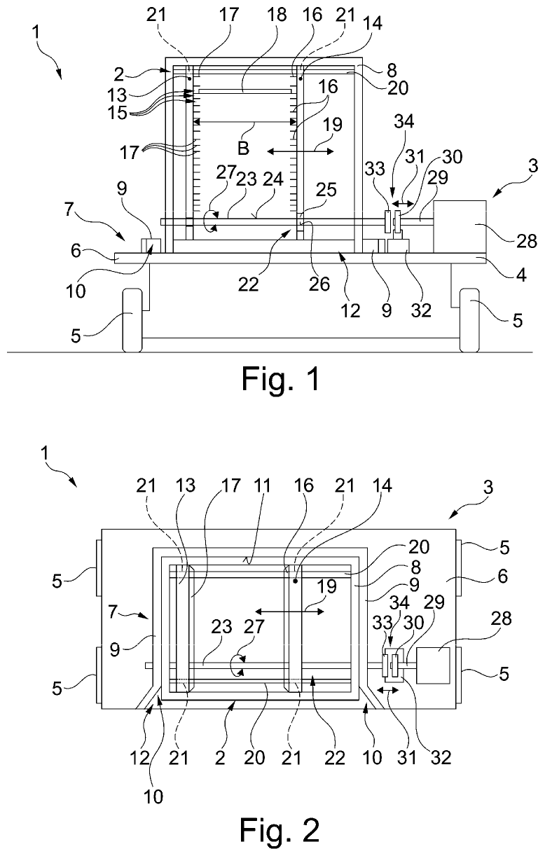

FIG. 1 shows in a simplified side view an advantageous substrate magazine system 1 comprising a substrate magazine 2 and a substrate handling device 3. The substrate handling device 3 is designed as a transport vehicle 4 which, according to the present exemplary embodiment, is designed as an autonomously operating motor vehicle which has a plurality of drivable wheels 5 of which at least one, preferably a plurality of wheels, can be steered, driven and/or braked. Alternatively, the transport vehicle 4 can also be a rail vehicle. Furthermore, according to another exemplary embodiment, the substrate handling device 3 is a loading and unloading device for an assembly line for flat substrates.

The substrate handling unit 3 has a storage table 6 on which the substrate magazine 2 is arranged. The storage table 6 has guide means 7 which are used for aligning and arranging the substrate magazine 2 on the storage table 6.

FIG. 2 shows the substrate magazine system in a simplified plan view. The substrate magazine 2 has a substantially rectangular frame 8 which has a square or rectangular footprint. The guide means 7 of the storage table 6 are designed in such a way that they orient the frame 8 of the substrate magazine 2 in the desired position. For this purpose, the guide means 7 have a guide ridge 9 which extends over the storage table 6 in a U-shape. The two opposite legs of the guide ridge 6 are oriented at their free ends to run obliquely outward so that a lead-in chamfer for a substrate magazine 2 results. Otherwise, the distance between the opposite legs of the U-shaped guide ridge 9 corresponds at least substantially to the width of the frame 8 of the substrate magazine 2 so that the substrate magazine 2 is aligned by the guide ridge. The central section of the guide ridge 9 connecting the two opposite legs to each other serves as an end stop 11 for the substrate magazine 2 in the substrate magazine receptacle 12 formed by the guide ridge 9. The substrate magazine 2 is thus insertable into the substrate magazine receptacle 12 at most up to the end stop 11 and is aligned therein by the guide means 7 during insertion.

The substrate magazine 2 has two side walls 13, 14 which are arranged on the frame 8 and are arranged at a distance from each other and are oriented vertically in parallel to each other, as also shown in FIG. 1. A plurality of compartments 15 are formed between the side walls 13, 14. Each compartment 15 is formed by two guide rails 16, 17 which are arranged in each case on one of the side walls 14, 15 on the mutually facing sides of the respective side wall 13, 14. The guide rails 16, 17 of a compartment 15 are arranged opposite each other at the same height in such a way that a distance also remains between the guide rails 17, 16.

A flat substrate 18, such as a printed circuit board, solar cell, wafer or the like, can thus be arranged in one of the compartments 15 in such a way that with its side edge regions that face away from each other, it rests on in each case one of the guide rails 16, 17, as shown by way of example in FIG. 1. Due to the distance of the guide rails 16, 17 from each other, this means that the central region, in particular the largest region of the respective substrate does not rest on anything and is instead free so that even populated substrates can be securely held in the substrate magazine 2 without possibly damaging, for example, structures formed on the substrates 18 or electrical/electronic components arranged on the substrates.

In order to ensure that substrates 18 of different widths B can be transported, stored or temporarily stored in the substrate magazine 2, the side wall 14 is displaceably mounted in such a way that the clear width between the side walls 13, 14 can be changed, as indicated by a double arrow 19. This makes it possible to change the width of the compartments 15 of the substrate magazine 2 so that the substrate magazine 2 can be adapted to different substrates to be processed.

For the displaceable mounting of the side wall 14, the side wall 14 is displaceably mounted on the frame 8. For this purpose, guide rods 20 are present, for example, which are fixedly arranged in the frame 8 and which each penetrate a guide opening 21 in the side wall 14 substantially without play. The side wall 14 is thus displaceable along the guide rods 20 in the frame 8.

In addition, a spindle drive 22 is advantageously assigned to the side wall 14. The spindle drive 22 has a drive spindle 23 which is oriented in parallel to the guide rods 20 and is rotatably mounted on the frame 8. The drive spindle 23 has an external thread 24. The side wall 14 has a spindle nut 25 which is either integrally formed in the side wall 14 or is fastened to the side wall 14 as a separate component. The spindle nut 25 has an internal thread 26 which engages with the external thread 24 of the drive spindle 23. When the drive spindle 23 is now set in rotational motion according to the double arrow 27, the rotational movement of the drive spindle 23 is converted into a translational movement of the side wall 14 according to the double arrow 19 and the clear width between the side walls 13, 14 is changed by the displacement of the side wall 14.

For this purpose, the substrate handling unit 3 has a first actuator 28 which is designed to drive the drive spindle 20. The actuator 28 is designed as an electric motor which has a drive shaft 29. A coupling element 30 is arranged at a free end of the drive shaft 29. The coupling element 30 is connected in a rotationally fixed manner to the drive shaft 29 and is axially displaceably mounted thereon, as shown by a double arrow 31. A second actuator 32 is assigned to the coupling element 30 and is designed to displace the coupling element 30 axially along the drive shaft 29 without thereby impeding its rotational movement or rotation. The second actuator is embodied in particular as a pneumatic or hydraulic actuator 32.

At a free end, the drive spindle 23 has a second coupling element 33 which is arranged in a rotationally fixed and in particular also axially fixed manner on the drive spindle 23. The coupling elements 30 and 33 can be brought into operative connection with each other by the displacement of the coupling element 30. In this case, the coupling elements 30, 33 are designed to form a coupling 34 between the actuator 28 and the spindle drive 22. In the final storage position of the substrate magazine 2 in the substrate magazine receptacle 12, the coupling element 33 lies opposite the coupling element 30 so that the operative connection can be established by means of the second actuator 32 by a simple axial displacement of the coupling element 30.

The advantageous embodiment of the substrate magazine system 1 thus allows the clear width of the compartments 15 of the substrate magazine 2 to be adaptable without the substrate magazine 2 itself needing to have an actuator required for this purpose. Instead, the actuator 28 is arranged stationarily or locally on the substrate handling device 3 and can be operatively connected to the substrate magazine 2 by the coupling 34. The guide means 7 ensure that a simple positioning of the coupling element 33 opposite the coupling element 30 is ensured. An automatic alignment is thus effected by the guide means 7 when the substrate magazine 2 is inserted into the substrate magazine receptacle 12.

The coupling elements 30, 33 are advantageously designed to form a friction coupling so that a particularly precise adjustment of the side wall 14 is achieved by means of static friction between the coupling elements 30, 33. For this purpose, the coupling elements 30, 33 are designed in particular as friction disks. Alternatively, however, the coupling 34 can also be designed as a dog coupling, which makes possible a form-fitting connection for transmitting the drive torque of the actuator 28 to the spindle drive 23.

The substrate magazine system 1 advantageously has a plurality of substrate magazines 2 which are designed as described above. The substrate magazines 2 can thus each be arranged in the substrate magazine receptacle 12 and adapted or adjusted to a desired substrate width by means of the actuators 28, 32.

The spindle drive 23 ensures that accidental displacement of the side wall 14 without the spindle drive 22 being driven is prevented. This is ensured by the self-locking action of the spindle drive 22.

1. A substrate magazine system for loading or unloading devices on production lines, comprising:
at least one substrate magazine comprising:
two side walls arranged at a distance from each other and oriented in parallel to each other, between which a plurality of compartments lying one above the other is defined;
a plurality of guide rails on each of the side walls,
wherein the compartments are each configured for the storage of one or more flat substrates, and
wherein each compartment is formed by two opposing guide rails including a guide rail on each of the two side walls,
wherein the opposing guide rails are arranged at a distance from each other,
wherein at least one of the side walls is displaceably mounted for changing a clear width between the side walls, and
at least one substrate handling device configured to interface with the at least one substrate magazine for handling substrates disposed in the compartments,
wherein the substrate handling device has a first actuator configured to be connected by an actuatable coupling to the displaceably mounted side wall and is configured in the connected state to displace the displaceable side wall.

2. The substrate magazine system according to claim 1, wherein the substrate magazine has a spindle drive which is assigned to the displaceably mounted side wall and is configured to be connected to the first actuator by the actuatable coupling.

3. The substrate magazine system according to claim 2, wherein the spindle drive has a drive spindle which has a first coupling element at a first free end, wherein the first actuator has a drive shaft which has a second coupling element at a second free end, wherein the first and the second coupling element together form the actuatable coupling.

4. The substrate magazine system according to claim 3, wherein at least one of the coupling elements is displaceable in order to establish or release a connection between the drive spindle and the drive shaft.

5. The substrate magazine system according to claim 4, wherein a second actuator is assigned to the at least one of the coupling elements that is displaceable and wherein the second actuator is configured for displacing the displaceable coupling element.

6. The substrate magazine system according to claim 5, wherein the substrate handling unit has the first and/or second actuator.

7. The substrate magazine system according to claim 3, wherein the coupling elements form a friction coupling.

8. The substrate magazine system according to claim 3, wherein the coupling elements form a dog coupling.

9. The substrate magazine system according to claim 3, wherein the second coupling element is mounted on the drive shaft in a rotationally fixed and axially displaceable manner.

10. The substrate magazine system according to claim 3, wherein the first actuator comprises an electric motor.

11. The substrate magazine system according to claim 1, wherein the substrate handling unit has a storage table configured to receive at least one substrate magazine.

12. The substrate magazine system according to claim 11, wherein:
the substrate magazine has a spindle drive which is assigned to the displaceably mounted side wall and is configured to be connected to the first actuator by the actuatable coupling,
the spindle drive has a drive spindle comprising a first coupling element at a first free end, wherein the first actuator has a drive shaft comprising a second coupling element at a second free end, wherein the first and the second coupling element together form the actuatable coupling, and
the storage table has a guide through which the at least one substrate magazine on the storage table is guided into a final storage position in which the coupling elements of the substrate magazine are opposite each other.

13. The substrate magazine system according to claim 1, wherein the substrate handling unit is a loading and/or an unloading device for a production line.

14. The substrate magazine system according to claim 1, wherein the substrate handling unit is a trolley.
